(19) United States
(12) Patent Application Publication
(10) Pub. No.: US 2006/0014082 A1
(43) Pub. Date: Jan. 19, 2006

(54) Method of correcting mask pattern

(75) Inventor: Kazuhisa Ogawa, Kanagawa (JP)

Correspondence Address: RADER FISHMAN & GRAUER PLLC, LION BUILDING, 1233 20TH STREET N.W., SUITE 501, WASHINGTON, DC, 20036, US

(73) Assignee: Sony Corporation, Tokyo (JP)

(21) Appl. No.: 10/529,385

(22) PCT Filed: Sep. 30, 2003
(86) PCT No.: PCT/JP03/12493

§ 371 Date: Mar. 28, 2005

(30) Foreign Application Priority Data
Oct. 2, 2002 (JP) 2002-290372

(51) Int. Cl. G03C 5/00; G03F 1/00

(52) U.S. Cl. 430/5; 430/322; 430/30; 430/394

(57) ABSTRACT

A mask pattern correction method able to easily eliminate a fine step difference generated after line width correction of a pattern is provided. This is made a correction method of a mask pattern comprising a step of finding a difference between a graphic obtained by oversizing a pattern including a corner and temporary regions formed by shifting the pattern edge; a step of extracting an edge not contacting the line width corrected figure (region designation edge) from the difference; a step of forming a rectangle having the region designation edge as one side; and a step of deleting the rectangle from the difference to obtain a pattern burying the fine step difference.

### TECHNICAL FIELD

The present invention relates to a method of correcting the patterns of a mask used for lithography.

### BACKGROUND ART

Demands for miniaturization of semiconductor devices have become increasingly strong in recent years. The design rule has now reached less than ½ of the exposure wavelength of lithography. Attention is being focused on electron beam lithography as lithography technology able to realize further miniaturization of devices.

Along with the miniaturization of the patterns, the problem has arisen that the patterns on the mask and the actually transferred patterns will differ (proximity effect). In order to reduce the influence of the proximity effect, proximity effect correction is applied to the mask patterns. As one type of proximity effect correction, there is line width correction processing.

Line width correction processing is mask pattern data processing adjusting the line width of each interconnect by exactly a previously prescribed shift amount in accordance with the line width of the interconnect and the distance between the interconnect and the adjacent interconnect and is widely used. Specifically, it performs a graphic operation comprising extracting a pattern edge (hereinafter also referred to as an “edge”) satisfying the two conditions of the line width and the distance and shifting the edge in the vertical direction with respect to that edge by exactly the prescribed amount. The edges before and after the line width correction processing become parallel to each other.

When performing line width correction based on the line width and the distance between interconnects as described above, however, a depressed part or a projecting part having a step difference of the same extent as the correction amount is formed. For example, as shown in FIG. 1, where correction amounts a and b are different from each other at sides adjoining via a 90° corner of a pattern I, a depressed part D is generated at the corner (part surrounded by circle).

When the angle of a corner is other than 90° as well, a depressed part or a projecting part is generated at the corner part due to the line width correction. For example, as shown in FIG. 2, at a 135° corner of a pattern II, a depressed part D having an angle of 45° is generated between correction patterns C1 and C2 (part surrounded by circle).

Further, for example, as shown in FIG. 3, at a 225° corner of a pattern III, a depressed part D having an angle of 45° is generated between correction patterns C1 and C2 (part surrounded by circle).

As shown in FIG. 4, when the correction pattern C is added to one of the sides adjoining each other via a 135° corner of a pattern IV, a projecting part P is generated at the corner (part surrounded by circle).

On the other hand, when adjacent interconnects are not parallel, as shown in FIG. 5A, the distance between interconnects continuously changes. The correction amount is defined in a discrete manner by the multiple of the minimum grid. Therefore, even if the correction amount of the correction pattern continuously changes, in the pattern actually formed on the mask, as shown in FIG. 5B, a stepped correction pattern obtained by combining rectangular patterns is prepared. Namely, a uniform correction amount is applied to each part where the line width and the distance between interconnects are within predetermined ranges.

As described above, if performing line width correction processing, a depressed part or a projecting part is generated at the corner of a pattern or a stepped correction pattern is generated at a pattern extending in a slanted direction. When there is such a depressed part or projecting part or stepped pattern, the number of graphics of the mask data increases and the data transfer time and drawing time for drawing the pattern on the mask become long.

Further, there is also the problem that a fine depressed part, projecting part, or stepped pattern generated due to line width correction will be falsely recognized as a fault in fault inspection of the mask. Due to such a pseudo fault, the time required for detecting faults will sometimes becomes long, or the fault inspection will sometimes be suspended.

As methods for eliminating a depressed part, projecting part, and other fine step difference, there are the method of enlarging the pattern by a constant amount exceeding the maximum correction amount (oversizing), burying the step difference, then reducing the pattern (undersizing) and the method of conversely undersizing, then oversizing the pattern.

A step difference can be buried according to such methods, but when the correction amount differs at sides adjoining a corner (for example refer to correction amounts a and b of FIG. 1), the problem arises that the correction amounts after burying the step difference will change, and the outer shape (topology) of the pattern will change due to the change of the correction amounts. If the correction amounts change, the correction for the proximity effect will be affected.

Further, in order to prepare and draw mask patterns in a short time, desirably patterns after line width correction can be touched up using a general purpose graphic processing tool such as provided in a mask lithographic system etc.

### DISCLOSURE OF THE INVENTION

The present invention was made in consideration of the above problems. Therefore, an object of the present invention is to provide a mask pattern correction method able to easily eliminate the fine step differences generated after line width correction of patterns.

To attain the above object, a mask pattern correction method of the present invention provides a method of correcting a mask pattern including a corner at which a first pattern extending in a first direction and a second pattern extending in a second direction are contiguous with each other while exhibiting a predetermined angle α°, comprising a step of making a first pattern edge comprised of one of the pattern edges extending in the first direction of the first pattern and present at an outside of the corner move in parallel in a third direction vertical to the first direction by a first correction amount to prepare a first correction pattern increasing a line width of the first pattern between the first pattern edge before and after making the first pattern edge move in parallel by the first correction amount; a step of making a second pattern edge comprised of one of the pattern edges extending in the second direction of the second pattern, present at an outside of the corner, and contiguous with the first pattern edge move in parallel in a fourth direction vertical to the second direction by a second correction amount to prepare a second correction pattern increasing a line width of the second pattern between the second pattern edge before and after making the second pattern edge move in parallel by the second correction amount; a step of enlarging a graphic comprised of the first pattern and the second pattern combined to prepare an enlarged graphic, which step enlarges the graphic so that the larger correction amount between the first correction amount and the second correction amount matches with the movement amount of the first pattern in the third direction and the larger correction amount matches with the movement amount of the second pattern in the fourth direction; a step of making the first pattern edge move in parallel in the third direction by the larger correction amount to prepare a first temporary region between the first pattern edge before and after making the first pattern edge move in parallel by the larger correction amount; a step of making the second pattern edge move in parallel in the fourth direction by the larger correction amount to prepare a second temporary region between the second pattern edge before and after making the second pattern edge move in parallel by the larger correction amount; a step of removing the first temporary region and the second temporary region from the enlarged graphic to prepare a step difference burying pattern; a step of removing an outermost circumferential edge from all pattern edges of the step difference burying pattern and further removing the pattern edge of the first correction pattern and the pattern edge of the second correction pattern to extract a region designation edge; a step of making the region designation edge move in parallel in a direction vertical to the region designation edge and toward the inside of the step difference burying pattern by the larger correction amount to prepare a deletion region between the region designation edge before and after making the region resignation edge move in parallel by the larger correction amount; and a step of deleting the deletion region from the step difference burying pattern and adding the step difference burying pattern from which the deletion region was deleted and the first correction pattern and the second correction pattern to the first pattern and the second pattern.

In the mask pattern correction method of the present invention, preferably the step of enlarging the graphic is carried out by oversizing the first and/or the second pattern.

Alternatively, preferably, the step of preparing the first and/or the second temporary region is carried out by oversizing the first and/or the second pattern.

Alternatively, preferably, the removal of the first temporary region and the second temporary region is carried out by undersizing the first temporary region and the second temporary region.

Alternatively, preferably, the correction amounts of the first correction pattern and the second correction pattern are different from each other.

Alternatively, preferably, the outermost circumferential edge is the part of a line segment extending in the first direction in the edge of the first temporary region and the part of the line segment extending in the second direction in the edge of the second temporary region.

Alternatively, preferably, the larger correction amount is a maximum correction amount of either the first correction amount or the second correction amount.

Alternatively, preferably the predetermined angle α° is defined by 90≦α<180.

Alternatively, to attain the above object, a mask pattern correction method of the present invention provides a method of correcting a mask pattern including a corner at which a first pattern extending in a first direction and a second pattern extending in a second direction are contiguous with each other while exhibiting a predetermined angle α°, comprising a step of making a first pattern edge comprised of one of the pattern edges extending in the first direction of the first pattern and present at the inside of the corner move in parallel in a third direction vertical to the first direction by a first correction amount to prepare a first correction pattern increasing the line width of the first pattern between the first pattern edge before and after making the first pattern edge move in parallel by the first correction amount; a step of making a second pattern edge comprised of one of the pattern edges extending in the second direction of the second pattern and present at the inside of the corner and contiguous with the first pattern edge move in parallel in a fourth direction vertical to the second direction by a second correction amount to prepare a second correction pattern increasing the line width of the second pattern between the second pattern edge before and after making the second pattern edge move in parallel by the second correction amount; a step of extracting a region designation edge having a length not more than the larger correction amount between the first correction amount and the second correction amount and having an angle at one end of 90° and an angle at the other end of 450°-α° from the pattern edge of the first correction pattern and the pattern edge of the second correction pattern; a step of preparing a square having the region designation edge as one side so as not to overlap a correction pattern including the region designation edge; a step of extracting the edge in the square of the part in the square and not overlapping any side of the square from the pattern edge of the first correction pattern and the pattern edge of the second correction pattern; and a step of adding a triangle pattern surrounded by another side of the square adjacent to the region designation edge, the region designation edge, and the edge in the square, the first correction pattern, and the second correction pattern to the first pattern and the second pattern.

In the mask pattern correction method of the present invention, preferably the step of preparing the first and/or the second correction pattern is carried out by oversizing the first and/or the second pattern.

Alternatively, preferably, before the step of preparing the square, the first correction pattern and/or the second correction pattern is undersized.

Alternatively, preferably the correction amounts of the first correction pattern and the second correction pattern are different from each other.

Alternatively, preferably the larger correction amount is the maximum correction amount of either the first correction amount or the second correction amount.

Alternatively, preferably the predetermined angle α° is defined by 90≦α<180.

Alternatively, to attain the above object, a mask pattern correction method of the present invention provides a method of correcting a mask pattern including a corner at which a first pattern extending in a first direction and a second pattern extending in a second direction are contiguous with each other while exhibiting a predetermined angle α°, comprising a step of making a first pattern edge comprised of one of the pattern edges extending in the first direction of the first pattern and present at the outside of the corner move in parallel in a third direction vertical to the first direction by a predetermined correction amount to prepare a correction pattern increasing the line width of the first pattern between the first pattern edge before and after making the first pattern edge move in parallel by the predetermined correction amount; a step of extracting a region designation edge having a length not more than the predetermined correction amount and having an angle at one end of 90° and an angle at the other end of α°+90° from among pattern edges of the correction pattern; a step of preparing a square having the region designation edge as one side so as to overlap the correction pattern; a step of extracting the edge on the square overlapping the side of the square from among pattern edges of the correction pattern except the first pattern edge; a step of preparing a triangle pattern having the region designation edge and the edge on the square as two sides; and a step of deleting the triangle pattern from the correction pattern and adding the correction pattern from which the triangle pattern was deleted to the first pattern.

In the mask pattern correction method of the present invention, preferably the step of preparing the correction pattern is carried out by oversizing the first pattern.

Alternatively, preferably before the step of preparing the square, the correction pattern is undersized.

Alternatively, preferably the predetermined angle α° is defined by 90≦α<180.

Alternatively, to attain the above object, a mask pattern correction method of the present invention provides a method of correcting a mask pattern including a first pattern extending in a first direction and a second pattern extending in a second direction, comprising a step of dividing a first pattern edge comprised of one of the pattern edges extending in the first direction of the first pattern and present on the second pattern side into a plurality of sections; a step of making each divided section move in parallel in a third direction vertical to the first direction by a correction amount in accordance with a distance from the second pattern to prepare correction patterns increasing the line width of the first pattern between the section before and after making the section move in parallel; a step of extracting a plurality of first region designation edges shorter than the maximum correction amount extending in the third direction from among pattern edges of the correction patterns; a step of making each first region designation edge move in parallel toward the inside of the correction pattern in the first direction by the minimum value of the section length to prepare a first rectangular region between the first region designation edge before and after making the first region designation edge move in parallel; a step of extracting a plurality of second region designation edges shorter than the minimum value of the section length extending in the first direction from among pattern edges of the correction patterns; a step of making each second region designation edge move in parallel toward the inside of the correction pattern in the third direction by the maximum correction amount to prepare a second rectangular region between the second region designation edge before and after making the second region designation edge move in parallel; a step of deleting overlapping parts of the first rectangular regions and the second rectangular regions from the correction patterns; and a step of repeating the extraction of the first region designation edge, the preparation of the first rectangular region, the extraction of the second region designation edge, and the preparation of the second rectangular region until there are no longer any second region designation edges.

By this, it becomes possible to eliminate the fine step difference and stepped shape generated at the corner etc. of the pattern after the line width correction of the mask pattern for reducing the proximity effect by processing using a general purpose graphic processing tool. According to the mask pattern correction method of the present invention, the fine step difference generated in the mask pattern can be prevented from becoming pseudo error in fault inspection of the mask. Further, by eliminating the fine step difference, it becomes possible to reduce the amount of data processing and speed up the drawing etc. of a mask pattern.

### BRIEF DESCRIPTION OF THE DRAWINGS

FIG. 1 is a view showing a fine step difference generated after correcting the line width of a pattern.

FIG. 2 is a view showing a fine step difference generated after correcting the line width of a pattern.

FIG. 3 is a view showing a fine step difference generated after correcting the line width of a pattern.

FIG. 4 is a view showing a fine step difference generated after correcting the line width of a pattern.

FIG. 5A and FIG. 5B are views showing steps of the mask pattern correction method according to a conventional example and Embodiment 5 of the present invention.

FIG. 6A to FIG. 6C are views showing steps of the mask pattern correction method according to Embodiment 1 of the present invention.

FIG. 7A to FIG. 7D are views showing steps of the mask pattern correction method according to Embodiment 1 of the present invention.

FIG. 8A to FIG. 8C are views showing steps of the mask pattern correction method according to Embodiment 2 of the present invention.

FIG. 9A to FIG. 9C are views showing steps of the mask pattern correction method according to Embodiment 2 of the present invention.

FIG. 10 is a view showing a step of the mask pattern correction method according to Embodiment 2 of the present invention.

FIG. 11A to FIG. 11C are views showing steps of the mask pattern correction method according to Embodiment 3 of the present invention.

FIG. 12A to FIG. 12C are views showing steps of the mask pattern correction method according to Embodiment 3 of the present invention.

FIG. 13A to FIG. 13C are views showing steps of the mask pattern correction method according to Embodiment 4 of the present invention.

FIG. 14A to FIG. 14C are views showing steps of the mask pattern correction method according to Embodiment 4 of the present invention.

FIG. 15A to FIG. 15D are views showing steps of the mask pattern correction method according to Embodiment 5 of the present invention.

FIG. 16A to FIG. 16C are views showing steps of the mask pattern correction method according to Embodiment 5 of the present invention.

### BEST MODE FOR WORKING THE INVENTION

Below, an explanation will be given of embodiments of the mask pattern correction method of the present invention by referring to the drawings. The mask pattern correction method of the present invention has a step of performing line width correction on a prepared mask pattern, then eliminating a fine step difference generated at the corner etc. of the pattern.

In the following Embodiments 1 to 5, an explanation will be given of specific examples of the method of elimination of fine step differences. In each embodiment, the maximum correction amount is represented by Max(bias). “Max(bias)” is the maximum value of the amount of shift of a pattern edge in a right angle direction with respect to the edge thereof in the pattern (correction amount). Further, in each embodiment, the lower limit of the edge length desired as the final correction result is represented by Min(edge).

### Embodiment 1

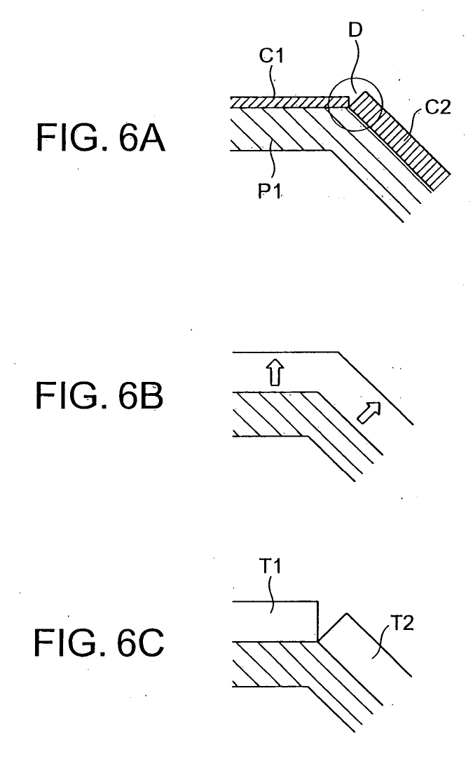

In the present embodiment, an explanation will be given of a method of eliminating a depressed part generated between correction patterns at the corner of a pattern due to the line width correction. FIG. 6A shows the corner of a pattern with a depressed part to be buried according to the present embodiment. A pattern P1 of FIG. 6A includes a corner of 135° (part surrounded by circle) in the same way as FIG. 2. Assume that the correction amounts of the correction patterns C1 and C2 on the two sides of the corner of 135° are different from each other.

In order to bury the depressed part D shown in FIG. 6A, first, as shown in FIG. 6B, the entire pattern is oversized by Max(bias). Next, as shown in FIG. 6C, the pattern edges are shifted in the vertical direction with respect to the edges by Max(bias). Due to this, temporary regions T1 and T2 are formed. The order of the oversizing shown in FIG. 6B and the shifting of the pattern edges shown in FIG. 6C may be reversed.

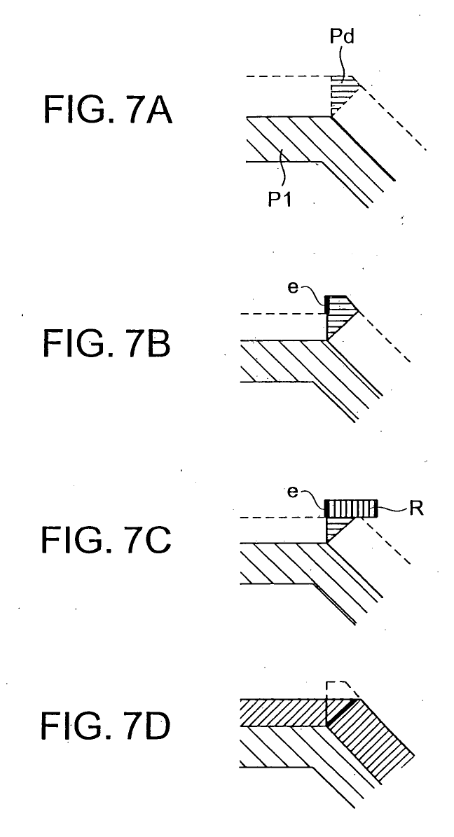

Next, as shown in FIG. 7A, a difference Pd between the pattern oversized in FIG. 6B and the total of the temporary regions T1 and T2 formed in FIG. 6C is found. From this difference Pd, a depressed part burying pattern is prepared.

Next, as shown in FIG. 7B, the pattern edges of the correction patterns C1 and C2 shown in FIG. 6A are removed from the edges of the difference Pd and the outermost circumferential edge of the difference Pd is removed. Due to this, an edge e indicated by a wide line in FIG. 7B is extracted from the edges of the difference Pd.

Next, as shown in FIG. 7C, the edge e extracted in FIG. 7B is shifted in the direction vertical to the edge e and the direction toward the inside of the difference Pd by Max(bias) to thereby generate a rectangular region R between the edge e before and after the shift.

Thereafter, as shown in FIG. 7D, the rectangular region R (refer to FIG. 7C) is deleted from the combination of the pattern after the line width correction (refer to FIG. 6A) and the difference Pd (refer to FIG. 7A).

Due to this, the depressed part of the corner is buried without changing the correction amounts on the two sides of the corner. Accordingly, the amount of data processing when drawing the mask data etc. is reduced, and the processing speed is raised. Further, in the fault inspection of the mask, it becomes possible to avoid detection of a fine step difference of the corner as a pseudo fault.

### Embodiment 2

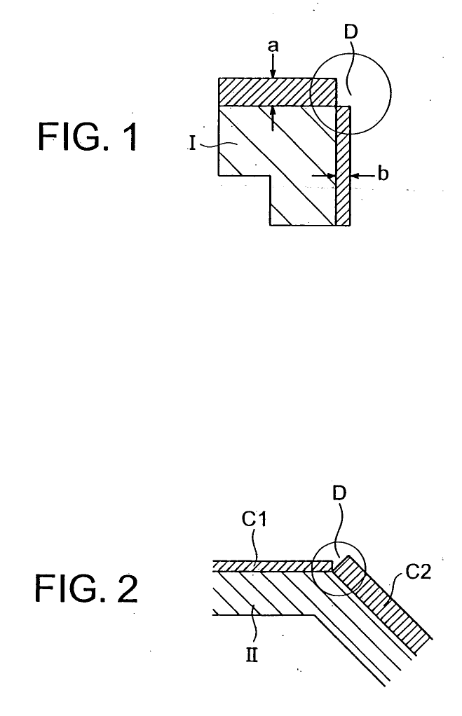

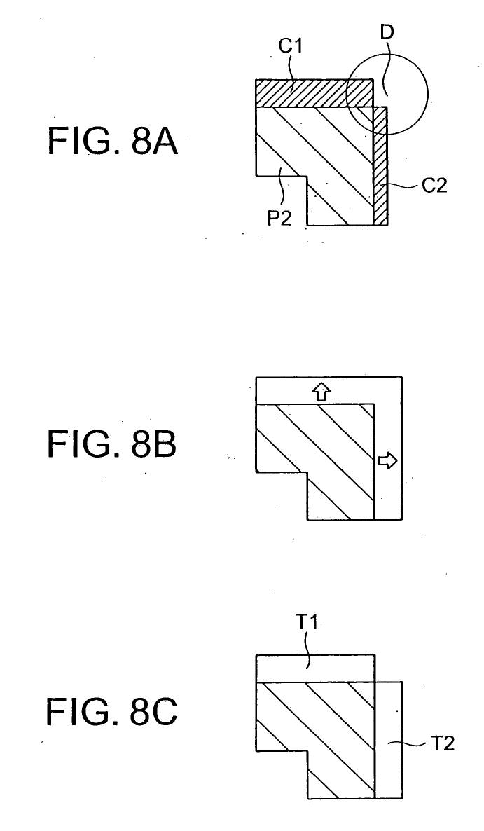

The present embodiment differs from Embodiment 1 in only the angle of the corner. FIG. 8A shows the corner of a pattern with a depressed part to be buried according to the present embodiment. A pattern P2 of FIG. 8A includes a corner of 90° (part surrounded by circle) in the same way as FIG. 1. Assume that the correction amounts of the correction patterns C1 and C2 on the two sides of the corner of 90° are different from each other.

In order to bury the depressed part D shown in FIG. 8A, first, as shown in FIG. 8B, the entire pattern is oversized by Max(bias). Next, as shown in FIG. 8C, the entire pattern edges are shifted in the vertical direction with respect to the edges by Max(bias) to form the temporary regions T1 and T2. The order of the oversizing shown in FIG. 8B and the shifting of the pattern edges shown in FIG. 8C may be reversed.

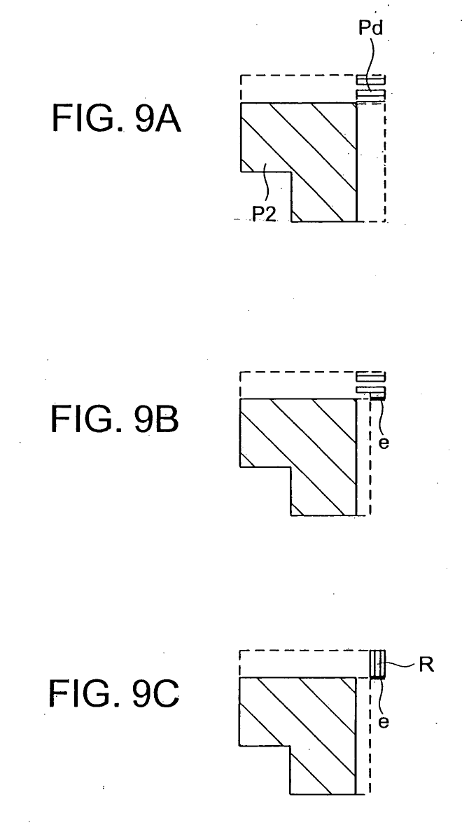

Next, as shown in FIG. 9A, the difference Pd between the pattern oversized in FIG. 8B and the total of the temporary regions T1 and T2 formed in FIG. 8C is found.

Next, as shown in FIG. 9B, the pattern edges of the correction patterns C1 and C2 shown in FIG. 8A are removed from the edges of the difference Pd and the outermost circumferential edge of the difference Pd is removed to extract the edge e indicated by the wide line in FIG. 9B.

Next, as shown in FIG. 9C, the edge e extracted in FIG. 9B is shifted in the direction vertical to the edge e and the direction toward the inside of the difference Pd by Max(bias) to thereby generate the rectangular region R between the edge e before and after the shift.

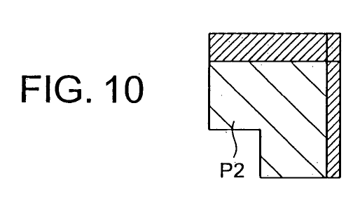

Thereafter, as shown in FIG. 10, the rectangular region R (refer to FIG. 9C) is deleted from the combination of the pattern after the line width correction (refer to FIG. 8A) and the difference Pd (refer to FIG. 9A).

Due to this, the depressed part of the corner is buried without changing the correction amounts on the two sides of the corner. Accordingly, the amount of data processing when drawing the mask data etc. is reduced, and the processing speed is raised. Further, in fault inspection of the mask, it becomes possible to avoid detection of a fine step difference of the corner as a pseudo fault.

### Embodiment 3

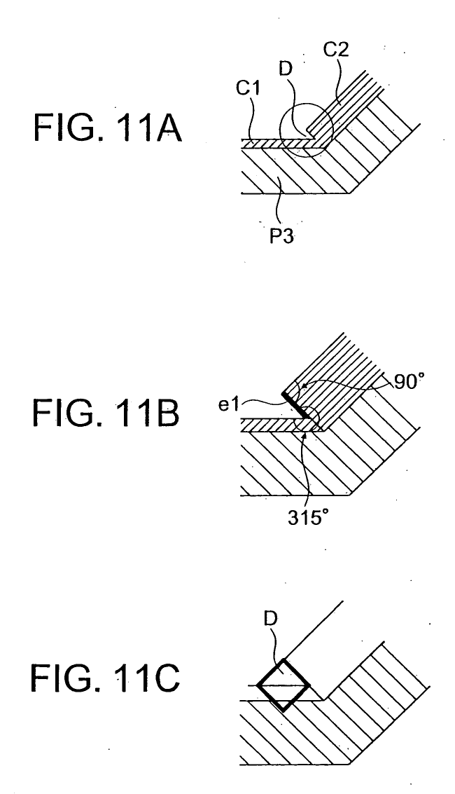

In the present embodiment, an explanation will be given of the method of eliminating a depressed part generated between correction patterns at the corner of a pattern due to line width correction. FIG. 11A shows the corner of a pattern with a depressed part to be buried according to the present embodiment.

In Embodiments 1 and 2, the corner of the pattern is less than 180°, but in contrast, in the present embodiment, the corner of the pattern is 225° in the same way as FIG. 3 and exceeds 180°. In this case, the correction pattern can be said to be formed at the inside of a corner of 135°.

In the present embodiment as well, assume that the correction amounts of the correction patterns C1 and C2 on the two sides of the corner differ from each other. As shown in FIG. 11A, when the corner of the pattern P3 exceeds 180°, correction patterns partially overlap at the corner of the pattern (part surrounded by circle).

In order to bury the depressed part D shown in FIG. 11A, first, as shown in FIG. 11B, an edge e1 comprised of a side having a length not more than Max(bias) and having interior angles at its two ends of 90° and 315° is extracted.

Next, as shown in FIG. 1C, a square having the edge e1 extracted in FIG. 11B as one side is formed. At this time, the square is arranged at the depressed part D between correction patterns.

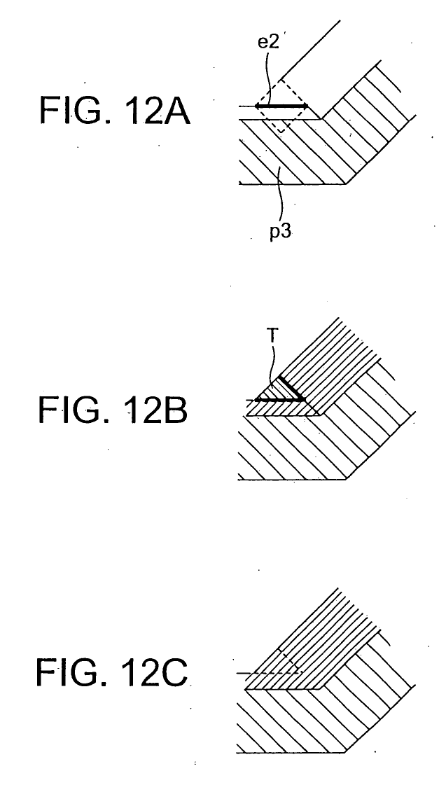

Next, as shown in FIG. 12A, an edge e2 of the correction pattern overlapping the internal part of the square formed in FIG. 11C, but not overlapping a side of the square is extracted.

Next, as shown in FIG. 12B, the region T surrounded by the edge e1 (refer to FIG. 11B), the edge e2 (refer to FIG. 12A), and one side of the square (refer to FIG. 1C) is buried.

Due to this, as shown in FIG. 12C, the depressed part of the corner is buried without changing the correction amounts at the two sides of the corner. Accordingly, the amount of data processing when drawing the mask data etc. is reduced, and the processing speed is raised. Further, in fault inspection of the mask, it becomes possible to avoid detection of a fine step difference of the corner as a pseudo fault.

### Embodiment 4

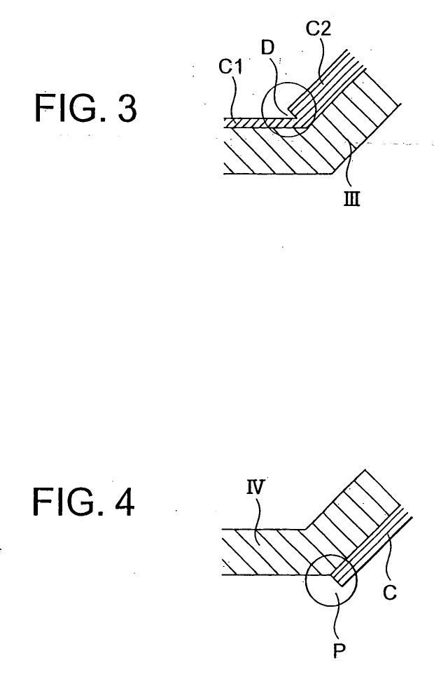

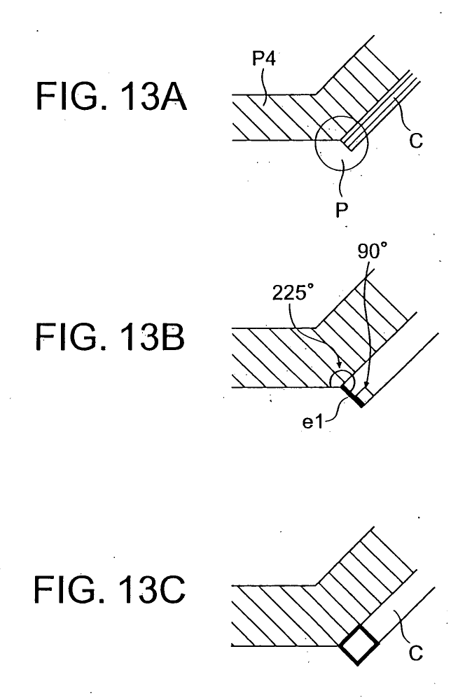

In the present embodiment, an explanation will be given of a method of eliminating a projecting part generated at a correction pattern at the corner of a pattern due to line width correction. FIG. 13A shows the corner of the pattern with a projecting part to be shaved according to the present embodiment. A pattern P4 of FIG. 13A includes a corner of 135° in the same way as FIG. 4 and has the correction pattern C added to the outside of the corner of 135° (part surrounded by circle).

In order to shave the projecting part P shown in FIG. 13A, first, as shown in FIG. 13B, an edge 1 having a length not more than Max(bias) and having interior angles at the two ends of 90° and 225° is extracted.

Next, as shown in FIG. 13C, a square having the edge e1 extracted in FIG. 13B as one side is formed. At this time, the square is arranged at the side overlapping the correction pattern C.

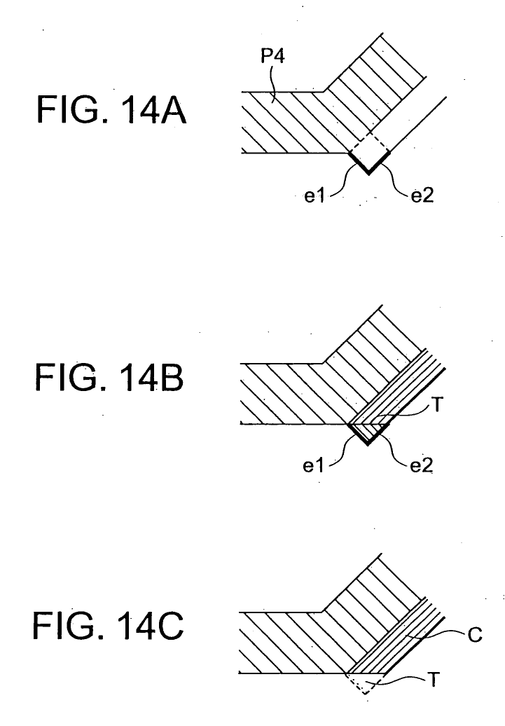

Next, as shown in FIG. 14A, an edge e2 of the correction pattern C at the part overlapping the square formed in FIG. 13C is extracted.

Next, as shown in FIG. 14B, a triangle region T having the edge 1 and the edge 2 as two sides is formed. Thereafter, as shown in FIG. 14C, the region T is deleted from the correction pattern C.

Due to this, the projecting part of the corner is shaved off without changing the correction amount of the line width. Accordingly, the amount of data processing when drawing the mask data etc. is reduced, and the processing speed is raised. Further, in fault inspection of the mask, it becomes possible to avoid detection of a fine step difference of the corner as a pseudo fault.

### Embodiment 5

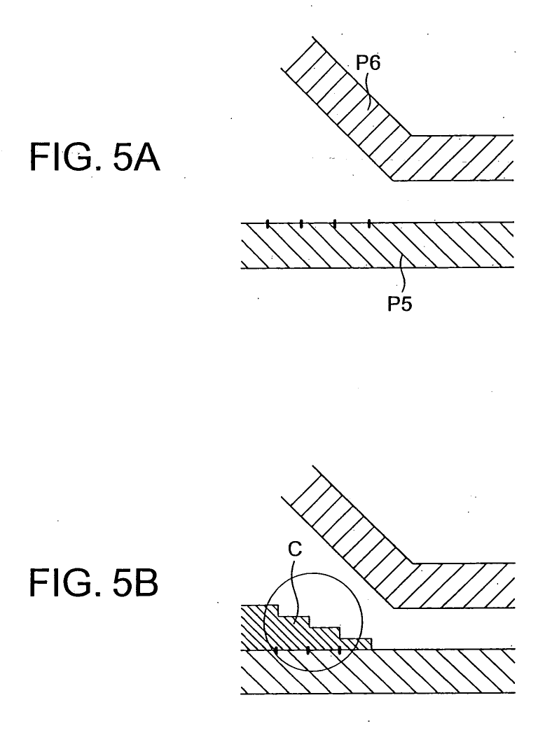

In the present embodiment, an explanation will be given of a method of preventing a pattern edge from becoming a stepped shape due to line width correction. FIG. 5A shows a pattern with a stepped part deleted according to the present embodiment.

In the patterns P5 and P6 of FIG. 5A, the adjoining interconnects are not parallel. The distance between the interconnects continuously changes. The correction amount is defined in a discrete manner by a multiple of the minimum grid, therefore, as shown in FIG. 5B, a correction pattern C stepwisely changing the correction amount is prepared. The correction amount changes in accordance with the distance between the interconnects.

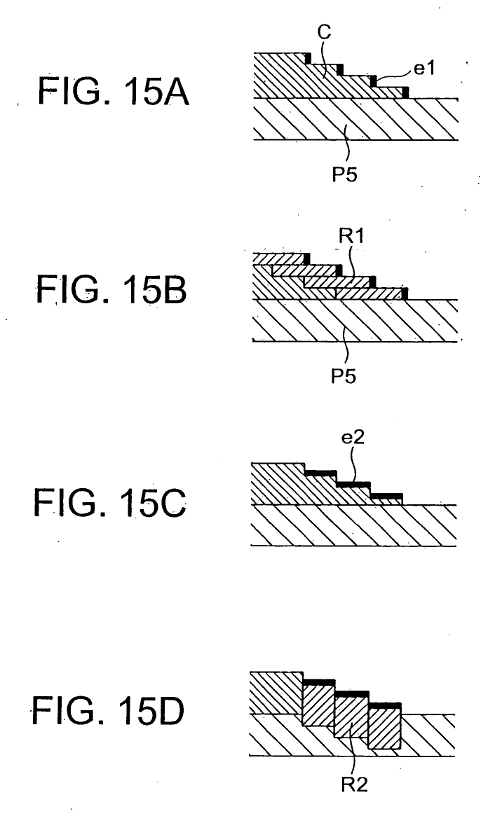

In order to delete the stepped part (part surrounded by circle) shown in FIG. 5B, first, as shown in FIG. 15A, edges e1 vertical to the pattern edge before the line width correction and having lengths not more than Max(bias) are extracted. The plurality of edges e1 extracted in this step are indicated by wide lines in FIG. 15A.

Next, as shown in FIG. 15B, the edges e1 extracted in FIG. 15A are shifted in the vertical direction with respect to the edges e1 and the direction toward the inside of the correction pattern C by Min(edge). Due to this, rectangular regions R1 are formed between the edge e1 before and after the shift. Since the correction pattern has a stepped shape, a plurality of rectangular regions R1 are formed.

On the other hand, as shown in FIG. 15C, the edges e2 parallel to the pattern edge before the line width correction and having lengths shorter than Min(edge) are extracted. The plurality of edges e2 extracted in this step are indicated by wide lines in FIG. 15C.

Next, as shown in FIG. 15D, the edges e2 extracted in FIG. 15C are shifted in the direction vertical with respect to the edges and the direction toward the inside of the correction pattern C by Max(bias). Due to this, rectangular regions R2 are formed between the edge e2 before and after the shift. Since the correction pattern has a stepped shape, a plurality of rectangular regions R2 are formed. The order of forming the rectangular regions R1 and the rectangular regions R2 may be reversed.

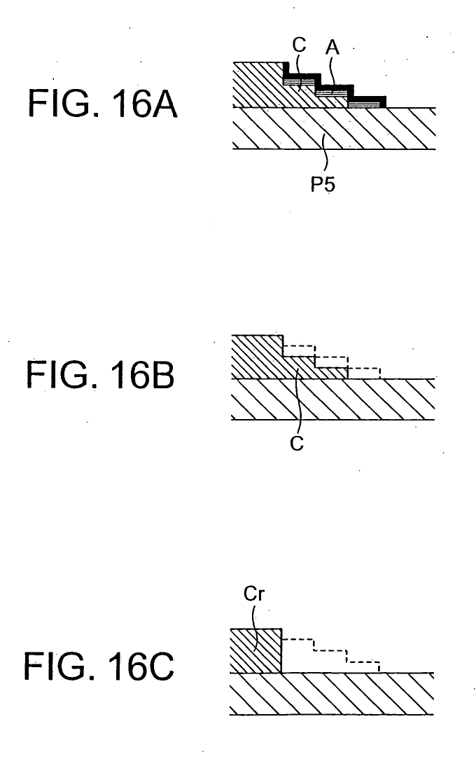

Next, as shown in FIG. 16A, overlapping parts (AND parts) A of the rectangular regions R1 and the rectangular regions R2 are found.

Next, as shown in FIG. 16B, the AND parts A of the rectangular regions R1 and the rectangular regions R2 (refer to FIG. 16C) are deleted from the correction pattern C.

Thereafter, the steps shown in FIG. 15A to FIG. 16B are repeated until the stepped shape is eliminated. Due to this, as shown in FIG. 16C, a rectangular correction pattern Cr is obtained.

According to the mask pattern correction method of the present embodiment described above, the part having a stepped shape is deleted in a correction pattern added to a pattern extending in a slanted direction. Accordingly, the amount of data processing when drawing the mask data etc. is reduced, and the processing speed is raised. Further, in fault inspection of a mask, it becomes possible to avoid detection of a fine step difference of the corner as a pseudo fault.

The embodiments of the mask pattern correction method of the present invention are not limited to the above explanation. For example, when adding correction patterns to both of the inside and outside of a corner to increase the line width of a pattern, it is also possible to correct the pattern by combining two different embodiments among the above embodiments.

Other than this, various modifications are possible within a range not out of the gist of the present invention.

According to the mask pattern correction method of the present invention, it becomes possible to easily eliminate a fine step difference generated after line width correction of a pattern.

### INDUSTRIAL APPLICABILITY

The mask pattern correction method of the present invention can be applied to the method of correction of a mask pattern for correcting the pattern of a mask used for lithography in the manufacturing process of a semiconductor device.

1. A method of correcting a mask pattern including a corner at which a first pattern extending in a first direction and a second pattern extending in a second direction are contiguous with each other while exhibiting a predetermined angle α°, comprising
a step of making a first pattern edge comprised of one of the pattern edges extending in the first direction of the first pattern and present at an outside of the corner move in parallel in a third direction vertical to the first direction by a first correction amount to prepare a first correction pattern increasing a line width of the first pattern between the first pattern edge before and after making the first pattern edge move in parallel by the first correction amount;
a step of making a second pattern edge comprised of one of the pattern edges extending in the second direction of the second pattern, present at an outside of the corner, and contiguous with the first pattern edge move in parallel in a fourth direction vertical to the second direction by a second correction amount to prepare a second correction pattern increasing a line width of the second pattern between the second pattern edge before and after making the second pattern edge move in parallel by the second correction amount;
a step of enlarging a graphic comprised of the first pattern and the second pattern combined to prepare an enlarged graphic, which step enlarges the graphic so that the larger correction amount between the first correction amount and the second correction amount matches with the movement amount of the first pattern in the third direction and the larger correction amount matches with the movement amount of the second pattern in the fourth direction;
a step of making the first pattern edge move in parallel in the third direction by the larger correction amount to prepare a first temporary region between the first pattern edge before and after making the first pattern edge move in parallel by the larger correction amount;
a step of making the second pattern edge move in parallel in the fourth direction by the larger correction amount to prepare a second temporary region between the second pattern edge before and after making the second pattern edge move in parallel by the larger correction amount;
a step of removing the first temporary region and the second temporary region from the enlarged graphic to prepare a step difference burying pattern;
a step of removing an outermost circumferential edge from all pattern edges of the step difference burying pattern and further removing the pattern edge of the first correction pattern and the pattern edge of the second correction pattern to extract a region designation edge;
a step of making the region designation edge move in parallel in a direction vertical to the region designation edge and toward the inside of the step difference burying pattern by the larger correction amount to prepare a deletion region between the region designation edge before and after making the region designation edge move in parallel by the larger correction amount; and
a step of deleting the deletion region from the step difference burying pattern and adding the step difference burying pattern from which the deletion region was deleted and the first correction pattern and the second correction pattern to the first pattern and the second pattern.

2. A method of correcting a mask pattern as set forth in claim 1, wherein the step of enlarging the graphic is carried out by oversizing the first and/or the second pattern.

3. A method of correcting a mask pattern as set forth in claim 1, wherein the step of preparing the first and/or the second temporary region is carried out by oversizing the first and/or the second pattern.

4. A method of correcting a mask pattern as set forth in claim 1, wherein the removal of the first temporary region and the second temporary region is carried out by undersizing the first temporary region and the second temporary region.

5. A method of correcting a mask pattern as set forth in claim 1, wherein the correction amounts of the first correction pattern and the second correction pattern are different from each other.

6. A method of correcting a mask pattern as set forth in claim 1, wherein the outermost circumferential edge is the part of a line segment extending in the first direction in the edge of the first temporary region and the part of the line segment extending in the second direction in the edge of the second temporary region.

7. A method of correcting a mask pattern as set forth in claim 1, wherein the larger correction amount is a maximum correction amount of either the first correction amount or the second correction amount.

8. A method of correcting a mask pattern as set forth in claim 1, wherein the predetermined angle α° is defined by 90≦α<180.

9. A method of correcting a mask pattern including a corner at which a first pattern extending in a first direction and a second pattern extending in a second direction are contiguous with each other while exhibiting a predetermined angle α°, comprising
a step of making a first pattern edge comprised of one of the pattern edges extending in the first direction of the first pattern and present at the inside of the corner move in parallel in a third direction vertical to the first direction by a first correction amount to prepare a first correction pattern increasing the line width of the first pattern between the first pattern edge before and after making the first pattern edge move in parallel by the first correction amount;
a step of making a second pattern edge comprised of one of the pattern edges extending in the second direction of the second pattern and present at the inside of the corner and contiguous with the first pattern edge move in parallel in a fourth direction vertical to the second direction by a second correction amount to prepare a second correction pattern increasing the line width of the second pattern between the second pattern edge before and after making the second pattern edge move in parallel by the second correction amount;
a step of extracting a region designation edge having a length not more than the larger correction amount between the first correction amount and the second correction amount and having an angle at one end of 90° and an angle at the other end of 450°-α° from the pattern edge of the first correction pattern and the pattern edge of the second correction pattern;
a step of preparing a square having the region designation edge as one side so as not to overlap a correction pattern including the region designation edge;
a step of extracting the edge in the square of the part in the square and not overlapping any side of the square from the pattern edge of the first correction pattern and the pattern edge of the second correction pattern; and
a step of adding a triangle pattern surrounded by another side of the square adjacent to the region designation edge, the region designation edge, and the edge in the square, the first correction pattern, and the second correction pattern to the first pattern and the second pattern.

10. A method of correcting a mask pattern as set forth in claim 9, wherein the step of preparing the first and/or the second correction pattern is carried out by oversizing the first and/or the second pattern.

11. A method of correcting a mask pattern as set forth in claim 9, wherein before the step of preparing the square, the first correction pattern and/or the second correction pattern is undersized.

12. A method of correcting a mask pattern as set forth in claim 9, wherein the correction amounts of the first correction pattern and the second correction pattern are different from each other.

13. A method of correcting a mask pattern as set forth in claim 9, wherein the larger correction amount is the maximum correction amount of either the first correction amount or the second correction amount.

14. A method of correcting a mask pattern as set forth in claim 9, wherein the predetermined angle α° is defined by 90≦α<180.

15. A method of correcting a mask pattern including a corner at which a first pattern extending in a first direction and a second pattern extending in a second direction are contiguous with each other while exhibiting a predetermined angle α°, comprising
a step of making a first pattern edge comprised of one of the pattern edges extending in the first direction of the first pattern and present at the outside of the corner move in parallel in a third direction vertical to the first direction by a predetermined correction amount to prepare a correction pattern increasing the line width of the first pattern between the first pattern edge before and after making the first pattern edge move in parallel by the predetermined correction amount;
a step of extracting a region designation edge having a length not more than the predetermined correction amount and having an angle at one end of 90° and an angle at the other end of α°+90° from among pattern edges of the correction pattern;
a step of preparing a square having the region designation edge as one side so as to overlap the correction pattern;
a step of extracting the edge on the square overlapping the side of the square from among pattern edges of the correction pattern except the first pattern edge;
a step of preparing a triangle pattern having the region designation edge and the edge on the square as two sides; and
a step of deleting the triangle pattern from the correction pattern and adding the correction pattern from which the triangle pattern was deleted to the first pattern.

16. A method of correcting a mask pattern as set forth in claim 15, wherein the step of preparing the correction pattern is carried out by oversizing the first pattern.

17. A method of correcting a mask pattern as set forth in claim 15, wherein before the step of preparing the square, the correction pattern is undersized.

18. A method of correcting a mask pattern as set forth in claim 15, wherein the predetermined angle α° is defined by 90≦α<180.

19. A method of correcting a mask pattern including a first pattern extending in a first direction and a second pattern extending in a second direction, comprising
a step of dividing a first pattern edge comprised of one of the pattern edges extending in the first direction of the first pattern and present on the second pattern side into a plurality of sections;
a step of making each divided section move in parallel in a third direction vertical to the first direction by a correction amount in accordance with a distance from the second pattern to prepare correction patterns increasing the line width of the first pattern between the section before and after making the section move in parallel;
a step of extracting a plurality of first region designation edges shorter than the maximum correction amount extending in the third direction from among pattern edges of the correction patterns;
a step of making each first region designation edge move in parallel toward the inside of the correction pattern in the first direction by the minimum value of the section length to prepare a first rectangular region between the first region designation edge before and after making the first region designation edge move in parallel;
a step of extracting a plurality of second region designation edges shorter than the minimum value of the section length extending in the first direction from among pattern edges of the correction patterns;
a step of making each second region designation edge move in parallel toward the inside of the correction pattern in the third direction by the maximum correction amount to prepare a second rectangular region between the second region designation edge before and after making the second region designation edge move in parallel;
a step of deleting overlapping parts of the first rectangular regions and the second rectangular regions from the correction patterns; and
a step of repeating the extraction of the first region designation edge, the preparation of the first rectangular region, the extraction of the second region designation edge, and the preparation of the second rectangular region until there are no longer any second region designation edges.
